(19) United States
(12) Patent Application Publication
(10) Pub. No.: US 2023/0103122 A1
(43) Pub. Date: Mar. 30, 2023

(54) BATTERY DIAGNOSTIC DEVICE, METHOD, STORAGE MEDIUM, AND VEHICLE

(71) Applicant: TOYOTA JIDOSHA KABUSHIKI KAISHA, Toyota-shi (JP)

(72) Inventor: Naoki TSUDA, Toyota-shi (JP)

(73) Assignee: TOYOTA JIDOSHA KABUSHIKI KAISHA, Toyota-shi (JP)

(21) Appl. No.: 17/940,166

(22) Filed: Sep. 8, 2022

(30) Foreign Application Priority Data
Sep. 28, 2021 (JP) 2021-157649

(51) Int. Cl. G01R 31/392; B60L 58/16; H01M 10/42; G01R 31/367

(52) U.S. Cl. CPC G01R 31/392; B60L 58/16; H01M 10/4285; G01R 31/367; H01M 2220/20

(57) ABSTRACT

A battery diagnostic device that diagnoses a state of a battery, the battery diagnostic device including: a first acquisition unit that acquires the number of actual usage years of the battery; a second acquisition unit that acquires a full charge capacity of the battery; and a determination unit that performs deterioration determination of the battery based on the number of actual usage years and the full charge capacity, in which the determination unit determines that the battery has deteriorated when the number of actual usage years exceeds the number of determination years and the full charge capacity is less than a determination capacity.

### CROSS-REFERENCE TO RELATED APPLICATION

This application claims priority to Japanese Patent Application No. 2021-157649 filed on Sep. 28, 2021, incorporated herein by reference in its entirety.

### BACKGROUND

### 1. Technical Field

The present disclosure relates to a battery diagnostic device and the like for diagnosing a state of a battery mounted on a vehicle.

### 2. Description of Related Art

Japanese Unexamined Patent Application Publication No. 2016-125932 (JP 2016-125932 A) discloses a deterioration state estimation device that calculates an internal resistance value of a battery mounted on a vehicle based on a voltage value and a current value, and that estimates a deterioration state of the battery from the calculated internal resistance value.

### SUMMARY

Since the internal resistance value of the battery increases as the deterioration of the battery progresses, it is possible to estimate the deterioration state of the battery from the internal resistance value. However, the higher the temperature of the battery, the smaller the difference between the internal resistance value of a deteriorated battery and the internal resistance value of a normal battery that has not deteriorated. Therefore, when the temperature of the battery is high, there is a possibility that the deteriorated battery is erroneously determined to be in a normal state, and there is a problem that a diagnostic accuracy of the deterioration determination of the battery is decreased.

The present disclosure has been made in view of the above issue, and an object of the present disclosure is to provide a battery diagnostic device or the like capable of improving an estimation accuracy of deterioration determination of a battery.

In order to solve the above problem, one aspect of the disclosed technique is a battery diagnostic device that diagnoses a state of a battery, the battery diagnostic device including: a first acquisition unit that acquires the number of actual usage years of the battery; a second acquisition unit that acquires a full charge capacity of the battery; and a determination unit that performs deterioration determination of the battery based on the number of actual usage years and the full charge capacity, in which the determination unit determines that the battery has deteriorated when the number of actual usage years exceeds the number of determination years and the full charge capacity is less than a determination capacity.

According to the battery diagnostic device of the present disclosure, since the deterioration determination of the battery is performed based on the number of actual usage years and the full charged capacity of the battery, the diagnostic accuracy of the deterioration determination of the battery can be improved.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a functional block diagram of a battery diagnostic device according to the present embodiment and a peripheral portion thereof;

FIG. 2 is a flowchart of a battery deterioration determination process executed by the battery diagnostic device;

FIG. 3 is a diagram showing an example of a change in a full charge capacity in conjunction with the number of actual usage years of the battery; and

FIG. 4 is a diagram illustrating a battery deterioration determination method.

### DETAILED DESCRIPTION OF EMBODIMENTS

A battery diagnostic device of the present disclosure determines the deterioration of a battery based on a number of actual usage years of the battery and a full charge capacity. By this deterioration determination process, the diagnostic accuracy of the deterioration determination of the battery can be improved. Hereinafter, an embodiment of the present disclosure will be described in detail with reference to the drawings.

### Embodiment

### Configuration

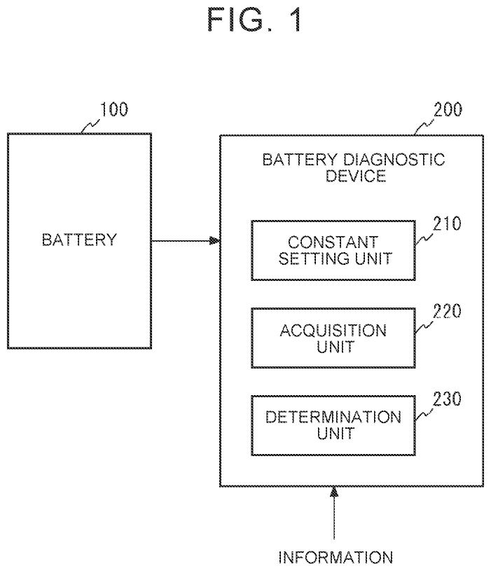

FIG. 1 is a functional block diagram of a battery diagnostic device according to an embodiment of the present disclosure and a peripheral portion thereof. The functional block illustrated in FIG. 1 includes a battery 100 and a battery diagnostic device 200. The battery 100 and the battery diagnostic device 200 are mounted on a vehicle, for example.

The battery 100 is a chargeable/dischargeable secondary battery such as a lithium ion battery, a nickel hydrogen battery, or a lead-acid battery. Examples of the battery 100 include a drive battery that supplies electric power required for a main engine apparatus (not shown) for driving a vehicle, an auxiliary battery that supplies electric power required for an auxiliary apparatus (not shown) that is not for driving a vehicle, and a sub-battery that backs up a main power supply during autonomous driving.

The battery diagnostic device 200 is a device for diagnosing the state of the battery 100, and more specifically, it can perform a diagnosis regarding deterioration of the battery 100. The battery diagnostic device 200 includes a constant setting unit 210, an acquisition unit 220, and a determination unit 230 in the configuration.

The constant setting unit 210 sets a “number of determination years Yb” and “determination capacity Cb” that are constants used in the deterioration determination process of the battery 100 performed by the determination unit 230 described later. This constant will be described.

The number of determination years Yb is a parameter for determining the deterioration of the battery 100 based on the amount of time the battery 100 was actually used. In this embodiment, this actual usage time is used as “number of actual usage years [unit: year]” in which the time is converted into years. This number of determination years Yb is set as follows.

First, a “number of warranty years Yw”, which is the period is which the performance of the battery 100 is guaranteed as a product, is set. This number of warranty years Yw is typically the number of years in which a manufacturing company, a sales company, or the like of the battery 100 prescribes the performance guarantee for the product. In this embodiment, an example in which the number of warranty years Yw is 5 years will be described (Yw=5).

Next, the “estimated number of usage years Yu”, which is the period in which the battery 100 is estimated to be used, is set based on a mode, purpose, environment, and the like in which the battery 100 is used. For example, when the battery 100 is used in a harsh environment, the number of estimated usage years Yu can be set relatively short, and when the battery 100 is used infrequently, the number of estimated usage years Yu can be set relatively long. In this embodiment, an example in which the number of estimated usage years Yu is 4 years will be described (Yu=4).

Next, an error that occurs when acquiring information regarding the usage time of the battery 100 is derived. Examples of the derived error include a “clock error Ce” that occurs in various systems that use the battery 100 and a “sampling error Se” that occurs when information about the usage time of the battery 100 is acquired.

As an example, the clock error Ce can be an error [unit: %] indicated by a percentage deviating from the normal system clock frequency. In this embodiment, the clock error Ce is 9% (Ce=0.09).

As an example, the sampling error Se can be an error [unit: second] per each act of acquiring information regarding the usage time. To give an example in which the battery 100 is mounted on a vehicle, the period in which the battery 100 is used is the period from when the ignition switch is turned on (IG-ON) to when the ignition switch is turned off (IG-OFF). In this embodiment, the sampling error Se is 59 seconds (Se=59). Since the sampling error Se occurs during this one on/off period, the sampling error “N×Se [unit: second]” per day can be obtained from the number of times N (estimated value) the ignition switch is turned on/off in a day. The number of times N that the ignition switch is turned on/off in one day can be calculated as N=W/I based on a vehicle operating time W (estimated value) per day and a frequency I (estimated value) that the ignition switch is turned on/off per day. In the present embodiment, the vehicle operating time W per day is set to 20 hours, and the frequency I that the ignition switch is switched on/off per day is set to 1.5 hours. Then, when the sampling error “N×Se [unit: second]” per day is converted into a year, it becomes “N×Se/3600/24 [unit: year]”.

Further, from the above-calculated clock error Ce [unit: %] and the sampling error “N×Se/3600/24 [unit: year]” per year, an upper limit number or years Ybh that is a possible upper limit value for the number of determination years Yb and a lower limit number of years Ybl that is a lower limit value that can be taken by the number of determination years Yb, in consideration of an error amount of each of the clock error Ce [unit: %] and the sampling error “N×Se/3600/24 [unit: year]”, are derived based on the following equations 1 and 2.

Upper limit number of years Ybh=number of determination years Yb+clock error Ce+sampling error Se=Yb×{(1+Ce)+N×Se/3600/24} [Equation 1]

Lower limit number of years Ybl=number of determination years Yb−clock error Ce−sampling error Se=Yb×{(1−Ce)−N×Se/3600/24} [Equation 2]

Then, the number of determination years Yb is set to a value that satisfies the conditions shown in the following Equation 3 based on the calculated upper limit number of years Ybh and lower limit number of years Ybl.

Number of estimated usage years Yu≤number of lower limit years Ybl<number of determination years Yb<upper limit number of years Ybh≤number of warranty years Yw [Equation 3]

For example, when the number of determination years Yb is 4.5 years, the lower limit number of years Ybl is 4.05 years, the upper limit number of years Ybh is 4.95 years, and the lower limit number of years Ybl, the number of determination years Yb, and the upper limit number of years Ybh are all included between the number of estimated usage years Yu that is 4 years and the number of warranty years Yw that is 5 years. Therefore, the constant setting unit 210 can set the number of determination years Yb to 4.5 years.

The number of determination years Yb may be set to any value as long as the condition shown in the above equation 3 is satisfied. Thus, for example, when you want to accelerate the deterioration determination of the battery 100, the number of determination years Yb may be set such that the number of estimated usage years Yu=the lower limit number of years Ybl is satisfied, and when you want to delay the deterioration determination of the battery 100, the number of determination years Yb may be set such that the upper limit number of years Ybh=the number of warranty years Yw is satisfied.

The determination capacity Cb is a parameter [unit: Ah] for determining the deterioration of the battery 100 based on the fully charged capacity of the battery 100. This determination capacity Cb is set as follows.

In the present embodiment, the determination capacity Cb is set to a value such that the battery 100 that has not reached a deterioration state presupposed at the time of design is not determined to be deteriorated, even when the number of actual usage years of the battery 100 exceeds the above-mentioned number of determination years Yb. FIG. 3 shows an example of a change (estimated value) in the full charge capacity in conjunction with the number of actual usage years of the battery 100.

As illustrated in FIG. 3, an average value of the designed full charge capacity (hereinafter referred to as an “estimated full charge capacity”) after 5 years, which is the period in which the performance of the battery 100 is guaranteed (number of warranty years Yw), has elapsed is 2.7 Ah. The constant setting unit 210 of the present embodiment sets 3.1 Ah that is a value of +3σ due to a standard deviation σ, which is a variation of the estimated full charge capacity, as the determination capacity Cb. By setting the determination capacity Cb in this way, the usable battery 100 can be utilized without waste.

It is also possible to set 2.5 Ah, which is a value of —3σ, as the determination capacity Cb. In this case, it can be determined that the battery 100, which may soon reach the deterioration state estimated at the time of design, is deteriorated. By setting the determination capacity Cb in this way, the effect of implementing safety measures at an early stage can be expected.

The acquisition unit 220 acquires the number of actual usage years of the battery 100 (first acquisition unit). In the present embodiment, a value [unit: year] obtained by integrating the time after the start of using the battery 100 (after selling the vehicle or after changing the battery) from when the ignition switch of the vehicle is turned on (IG-ON) until the ignition switch is turned off (IG-OFF), that is, a value obtained by integrating an operating time of the power supply system using the battery 100, is used as the number of actual usage years of the battery 100. The information on the number of actual usage years of the battery 100 may be accumulated and held by the battery diagnostic device 200 by itself, or may be acquired from another device mounted on the vehicle.

Further, the acquisition unit 220 acquires the full charge capacity of the battery 100 (second acquisition unit). The full charge capacity of the battery 100 can be calculated by using a well-known method such as a method of estimating the stored amount (SOC: State Of Charge) based on the current integration method. The information on the full charge capacity of the battery 100 may be calculated by the battery diagnostic device 200 by itself, or may be acquired from another device mounted on the vehicle.

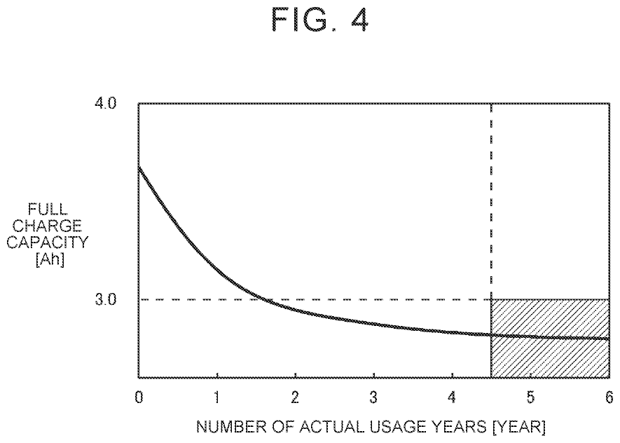

The determination unit 230 determines the deterioration of the battery 100 based on the number of actual usage years of the battery 100 acquired by the acquisition unit 220 and the full charge capacity. In this deterioration determination, as shown in a hatched region illustrated in FIG. 4, it is determined that the battery 100 is deteriorated when the number of actual usage years of the battery 100 is equal to or more than the number of determination years Yb and the full charge capacity of the battery 100 is equal to or more than the determination capacity Cb.

A part or all of the battery diagnostic device 200 described above may typically be configured as an electronic control unit (ECU) including a processor, a memory, an input/output interface, and the like. This ECU can realize some or all of the functions of the constant setting unit 210, the acquisition unit 220, and the determination unit 230 when the processor reads and executes the program stored in the memory.

### Control

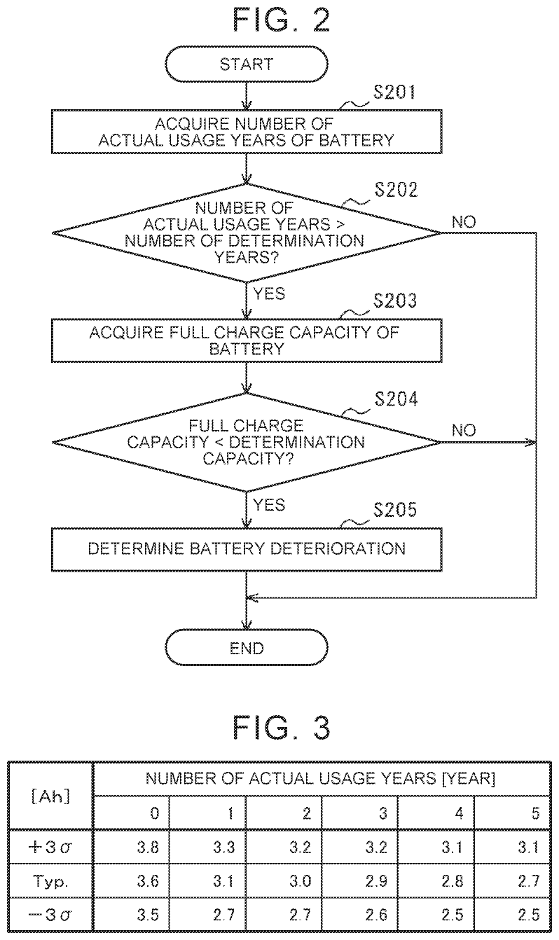

Next, with reference to FIG. 2, the control executed by the battery diagnostic device 200 according to the present embodiment will be described. FIG. 2 is a flowchart illustrating a procedure of a process (battery deterioration determination process) that is related to deterioration of the battery 100 and that is executed by the battery diagnostic device 200. The battery deterioration determination process illustrated in FIG. 2 is executed, for example, every time the ignition switch of the vehicle is turned on (IG-ON).

### Step S201

The acquisition unit 220 of the battery diagnostic device 200 acquires the number of actual usage years of the battery 100 at the time of performing the battery deterioration determination process. When the number of actual usage years of the battery 100 is acquired, the process proceeds to step S202.

### Step S202

The determination unit 230 of the battery diagnostic device 200 determines whether the number of actual usage years of the battery 100 exceeds the number of determination years Yb. When the number of actual usage years of the battery 100 exceeds the number of determination years Yb (S202, yes), the process proceeds to step S203. On the other hand, when the number of actual usage years of the battery 100 does not exceed the number of determination years Yb (S202, No), it is estimated that the battery 100 has not yet been determined to be deteriorated, and the battery deterioration determination process ends.

### Step S203

The acquisition unit 220 of the battery diagnostic device 200 acquires the full charge capacity of the battery 100 at the time of performing the battery deterioration determination process. When the full charge capacity of the battery 100 is acquired, the process proceeds to step S204.

### Step S204

The determination unit 230 of the battery diagnostic device 200 determines whether the full charge capacity of the battery 100 is less than the determination capacity Cb. When the full charge capacity of the battery 100 is less than the determination capacity Cb (S204, yes), the process proceeds to step S205. On the other hand, when the full charge capacity of the battery 100 is equal to or more than the determination capacity Cb (S204, No), it is estimated that the battery 100 has not yet been determined to be deteriorated, and the battery deterioration determination process ends.

### Step S205

The determination unit 230 of the battery diagnostic device 200 determines that the battery 100 is deteriorated. The result of this determination is notified, for example, to the user of the vehicle and the like, and a replacement of the battery 100 is urged. When the deterioration of the battery 100 is determined, the battery deterioration determination process ends.

### Operations and Effects

As described above, according to the battery diagnostic device 200 according to the embodiment of the present disclosure, the deterioration determination of the battery 100 is performed based on the number of actual usage years of the battery 100 and the fully charged capacity of the battery 100, instead of using an internal resistance value of the battery 100 that is affected by a battery temperature and the like. By this deterioration determination process, the diagnostic accuracy of the deterioration determination of the battery 100 can be improved.

Although the embodiments of the present disclosure have been described above, the present disclosure can be applied to a battery diagnostic device, a battery diagnostic method executed by a battery diagnostic device including a processor and a memory, a control program for executing a battery diagnostic method, a computer-readable non-transitory storage medium that stores a control program, and a vehicle equipped with a battery diagnostic device.

The battery diagnostic device of the present disclosure and the like can be used for diagnosing the state of a battery mounted on a vehicle.

What is claimed is:

1. A battery diagnostic device that diagnoses a state of a battery, the battery diagnostic device comprising:
a first acquisition unit that acquires the number of actual usage years of the battery;
a second acquisition unit that acquires a full charge capacity of the battery; and
a determination unit that performs deterioration determination of the battery based on the number of actual usage years and the full charge capacity,
wherein the determination unit determines that the battery has deteriorated when the number of actual usage years exceeds the number of determination years and the full charge capacity is less than a determination capacity.

2. The battery diagnostic device according to claim 1, wherein the number of determination years is set based on a period in which the battery is estimated to be used and a period in which performance of the battery is guaranteed.

3. The battery diagnostic device according to claim 1, wherein the number of determination years is set to a value that satisfies Equation 1 below, based on a lower limit number of years obtained by subtracting a predetermined error amount from the number of determination years, an upper limit number of years obtained by adding the error amount to the number of determination years, a number of estimated usage years that is a period in which the battery is estimated to be used, and a number of warranty years that is a period in which performance of the battery is guaranteed.
Number of estimated usage years≤lower limit number of years<number of determination year<upper limit number of years≤number of warranty years [Equation 1]

4. The battery diagnostic device according to claim 1, wherein the determination capacity is set based on the full charge capacity estimated at a time when a period in which performance of the battery is guaranteed expires.

5. The battery diagnostic device according to claim 4, wherein the determination capacity is set to a value that satisfies Equation 2 below, based on an estimated full charge capacity that is estimated at the time when the period in which the performance of the battery is guaranteed expires and a standard deviation that is a variation of the estimated full charge capacity.
Determination capacity=estimated full charge capacity+3×standard deviation [Equation 2]

6. A method executed by a computer of a battery diagnostic device that diagnoses a state of a battery mounted on a vehicle, the method comprising:
a step of acquiring the number of actual usage years of the battery;
a step of acquiring a full charge capacity of the battery; and
a step of determining that the battery has deteriorated when the number of actual usage years exceeds the number of determination years and the full charge capacity is less than a determination capacity.

7. A non-transitory storage medium that stores a program executed by a computer of a battery diagnostic device that diagnoses a state of a battery mounted on a vehicle, the program comprising:
a step of acquiring the number of actual usage years of the battery;
a step of acquiring a full charge capacity of the battery; and
a step of determining that the battery has deteriorated when the number of actual usage years exceeds the number of determination years and the full charge capacity is less than a determination capacity.

8. A vehicle equipped with the battery diagnostic device according to claim 1.
